(19) United States
(12) Patent Application Publication
(10) Pub. No.: US 2025/0357902 A1
(43) Pub. Date: Nov. 20, 2025

(54) POWER AMPLIFICATION SYSTEM, POWER AMPLIFICATION METHOD, AND DIGITAL PREDISTORTION CIRCUIT

(71) Applicant: Murata Manufacturing Co., Ltd., Nagaokakyo-shi (JP)

(72) Inventors: John HOVERSTEN, Waltham, MA (US); Ty LEWIS, Waltham, MA (US); Yevgeniy TKACHENKO, Waltham, MA (US); Muneharu KATO, Nagaokakyo-shi (JP); Takeshi KOGURE, Nagaokakyo-shi (JP); Toshiki MATSUI, Nagaokakyo-shi (JP)

(21) Appl. No.: 19/291,013

(22) Filed: Aug. 5, 2025

Related U.S. Application Data
(63) Continuation of application No. PCT/JP2024/002941, filed on Jan. 30, 2024.
(60) Provisional application No. 63/444,292, filed on Feb. 9, 2023.

(51) Int. Cl. H03F 1/32; H03F 1/02; H03F 3/24

(52) U.S. Cl. CPC H03F 1/3258; H03F 1/0233; H03F 3/245; H03F 2200/105; H03F 2200/451

(57) ABSTRACT

A power amplification system includes: a power amplifier; an output switch circuit configured to selectively output at least one of three or more discrete voltages as a power supply of the power amplifier; and a digital predistortion circuit configured to generate distortions in an input signal of the power amplifier. In a first mode, the digital predistortion circuit is configured to generate distortions in an input signal of the power amplifier by using a first mathematical-expression model for digital predistortion with a first parameter set. In a second mode with a lower average voltage of the power supply than the first mode, the digital predistortion circuit generates the distortions by using at least a different parameter set from the first parameter set, such as a second mathematical-expression model for digital predistortion with a second parameter set or the first mathematical-expression model with a third parameter set.

### CROSS-REFERENCE TO RELATED APPLICATIONS

This application is a continuation of International Application No. PCT/JP2024/002941, filed on Jan. 30, 2024, which claims priority to U.S. Provisional Patent Application No. 63/444,292 filed on Feb. 9, 2023, the contents of each of which are hereby incorporated by reference in their entirety.

### TECHNICAL FIELD

The present disclosure relates to a power amplification system, a power amplification method, and a digital predistortion circuit.

### BACKGROUND

These days, with the application of a tracking technology to a power amplifier circuit, the power-added efficiency is being improved. U.S. Pat. No. 8,829,993 discloses a tracker circuit for D-ET (Digital Envelope Tracking) that supplies a power supply voltage which is varied to multiple discrete levels over time (hereinafter called multiple discrete voltages). U.S. Pat. No. 10,686,407 discloses a tracker circuit for SPT (Symbol Power Tracking) which supplies multiple discrete voltages.

### SUMMARY OF THE DISCLOSURE

In view of the foregoing, according to exemplary aspect of the present disclosure, when such multiple discrete voltages are supplied to a power amplifier, digital predistortion (DPD) can be employed to reduce nonlinear distortion which occurs when the power amplifier operates in a nonlinear region. By predistorting an input signal to be supplied to a power amplifier, DPD can cancel the nonlinear distortion in the power amplifier. In DPD, it is desirable to cancel a greater amount of nonlinear distortion with a smaller calculation load. That is, it is desirable to effectively improve the quality of a sending signal while the power consumption is being regulated.

Accordingly, the present disclosure provides a power amplification system, a power amplification method, and a digital predistortion circuit that are capable of effectively improving the quality of a sending signal while regulating the power consumption.

In an exemplary aspect, a power amplification system includes: a power amplifier; an output switch circuit configured to selectively output at least one of three or more discrete voltages to the power amplifier; and a digital predistortion circuit configured to predistort an input signal to be supplied to the power amplifier. The output switch circuit has a first mode in which, among the three or more discrete voltages, at least one of discrete voltages forming a first subset is selectively output, and a second mode in which, among the three or more discrete voltages, at least one of discrete voltages forming a second subset is selectively output. The average voltage of the first subset is higher than that of the second subset. In the first mode, the digital predistortion circuit predistorts an input signal to be supplied to the power amplifier by using one or more first parameters (also referred to as a first parameter set) for a first mathematical-expression model for digital predistortion. In the second mode, the digital predistortion circuit predistorts an input signal to be supplied to the power amplifier by using at least a different parameter set from the first parameter set, such as one or more second parameters (also referred to as a second parameter set) for a second mathematical-expression model for digital predistortion or one or more third parameters (also referred to as a third parameter set) for the first mathematical-expression model.

In another exemplary aspect, a power amplification method includes: selectively supplying, among three or more discrete voltages, at least one of discrete voltages forming a first subset to a power amplifier; predistorting a first input signal to be supplied to the power amplifier by using one or more first parameters (also referred to as a first parameter set) for a first mathematical-expression model for digital predistortion; amplifying the predistorted first input signal by using the at least one of the discrete voltages forming the first subset among the three or more discrete voltages; selectively supplying, among the three or more discrete voltages, at least one of discrete voltages forming a second subset to the power amplifier; predistorting a second input signal to be supplied to the power amplifier by using at least a different parameter set from the first parameter set, such as one or more second parameters (also referred to as a second parameter set) for a second mathematical-expression model for digital predistortion or one or more third parameters (also referred to as a third parameter set) for the first mathematical-expression model; and amplifying the predistorted second input signal by using the at least one of the discrete voltages forming the second subset among the three or more discrete voltages.

In another exemplary aspect, a digital predistortion circuit is a digital predistortion circuit configured to predistort an input signal to be supplied to a power amplifier. In a first mode in which, among three or more discrete voltages, at least one of discrete voltages forming a first subset is selectively output to the power amplifier, the digital predistortion circuit predistorts an input signal to be supplied to the power amplifier by using one or more first parameters (also referred to as a first parameter set) for a first mathematical-expression model for digital predistortion. In a second mode in which, among the three or more discrete voltages, at least one of discrete voltages forming a second subset is selectively output to the power amplifier, the digital predistortion circuit predistorts an input signal to be supplied to the power amplifier by using at least a different parameter set from the first parameter set, such as one or more second parameters (also referred to as a second parameter set) for a second mathematical-expression model for digital predistortion or one or more third parameters (also referred to as a third parameter set) for the first mathematical-expression model. The average voltage of the first subset is higher than that of the second subset.

A power amplification system according to an exemplary aspect of the present disclosure and other exemplary aspects of the disclosure can reduce nonlinear distortion.

### BRIEF DESCRIPTION OF THE DRAWINGS

FIG. 1A is a graph illustrating an example of the transition of a power supply voltage in an APT (Average Power Tracking) mode;

FIG. 1B is a graph illustrating an example of the transition of a power supply voltage in an A-ET (Analog Envelope Tracking) mode;

FIG. 1C is a graph illustrating an example of the transition of a power supply voltage in a D-ET mode;

FIG. 2 is a circuit diagram of a communication apparatus according to an exemplary embodiment;

FIG. 3 is a circuit diagram of tracker circuitry according to the exemplary embodiment; and

FIG. 4 is a flowchart illustrating a power amplification method according to the exemplary embodiment.

### DETAILED DESCRIPTION OF THE EMBODIMENTS

Embodiments of the disclosure will be described below in detail with reference to the drawings. All the embodiments described below illustrate general or specific examples. Numerical values, configurations, materials, elements, and positions and connection states of the elements illustrated in the following embodiments are only examples and are not intended to limit the disclosure.

The drawings are only schematically shown and are not necessarily precisely illustrated. For the sake of representing the disclosure, the drawings are illustrated in an exaggerated manner or with omissions or the ratios of elements in the drawings are adjusted. The shapes, positional relationships, and ratios of elements in the drawings may be different from those of the actual elements. In the drawings, substantially identical elements are designated by like reference numeral, and it is possible that an explanation of such elements be not repeated or be merely simplified.

In the circuit configurations of the disclosure, the phrase “A is connected to B” includes, not only the meaning that A is directly connected to B using a connecting terminal and/or a wiring conductor, but also the meaning that A is electrically connected to B via another circuit element. The phrase “A is directly connected to B” can mean that A is directly connected to B using a connecting terminal and/or a wiring conductor without another circuit element interposed between A and B. The phrase “C is connected between A and B” can mean that one end of C is connected to A and the other end of C is connected to B and that C is disposed in series with a path connecting A and B. The phrase “A path connecting A and B” can refer to a path constituted by a conductor which electrically connects A to B.

In the following description, the phrase “a terminal” can refer to a point at which a conductor within an element terminates. If the impedance of a conductor between elements is sufficiently low, a terminal can be interpreted, not as a single point, but as certain points on the conductor between the elements or as the entire conductor.

Terms representing the relationship between elements, such as “being parallel” and “being vertical”, terms representing the shape of an element, such as “being rectangular”, and ranges of numerical values are not necessarily to be interpreted in an exact sense, but to be interpreted in a broad sense. That is, such terms and ranges also cover substantially equivalent ranges, such as about several percent of allowance.

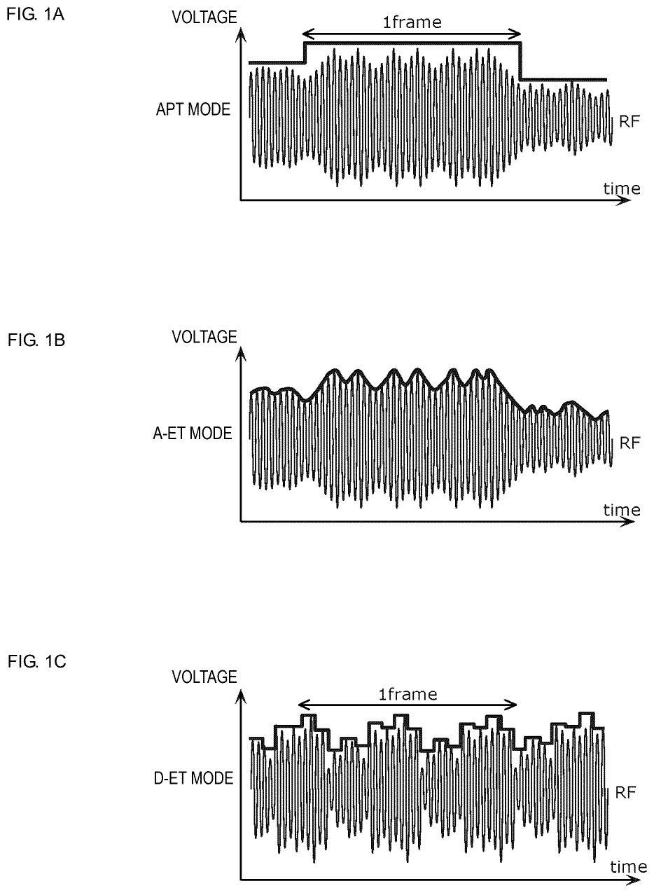

As a technology for amplifying a radio-frequency signal with high efficiency, a tracking mode in which a power supply voltage dynamically adjusted over time based on a radio-frequency signal is supplied to a power amplifier will first be discussed. The tracking mode is a mode in which the power supply voltage to be applied to a power amplifier is dynamically adjusted. There are several types of tracking modes. In this example, APT mode, A-ET mode, and D-ET mode will be explained below with reference to FIGS. 1A, 1B, and 1C, respectively. In FIGS. 1A through 1C, the horizontal axis indicates the time, and the vertical axis indicates the voltage. The thick solid line represents the power supply voltage, while the thin solid line (waveform) represents a modulated wave.

FIG. 1A is a graph illustrating an example of the transition of the power supply voltage in the APT mode. In the APT mode, based on average power, the power supply voltage is varied to multiple discrete voltage levels in units of frames. As a result, a power supply voltage signal forms a square wave.

A frame is a unit which forms a radio-frequency signal (modulated wave). For example, 5GNR (5th Generation New Radio) and LTE (Long Term Evolution) define that a frame includes ten subframes, each subframe includes plural slots, and each slot is constituted by plural symbols. The subframe length is 1 ms, and the frame length is 10 ms.

The mode in which the voltage level is varied in units of frames or in a larger unit based on average power is called the APT mode. The APT mode is distinguished from a mode in which the voltage level is varied in a unit (subframe, slot, or symbol, for example) smaller than a frame.

FIG. 1B is a graph illustrating an example of the transition of the power supply voltage in the A-ET mode. In the A-ET mode, the power supply voltage is continuously varied based on an envelope signal, so that the envelope of a modulated wave is tracked.

The envelope signal is a signal indicating the envelope of a modulated wave. The envelope value is represented by a square root of (I²+Q²), for example. (I, Q) is a constellation point. The constellation point is a point of a digital modulated signal on a constellation diagram. (I, Q) is determined by a BBIC (Baseband Integrated Circuit) based on sending information, for example.

FIG. 1C is a graph illustrating an example of the transition of the power supply voltage in the D-ET mode. In the D-ET mode, based on an envelope signal, the power supply voltage is varied to multiple discrete voltage levels in one frame, so that the envelope of a modulated wave is tracked. As a result, a power supply voltage signal forms a square wave.

### Exemplary Embodiment

An embodiment will be described below.

### 1.1 Circuit Configuration of Communication Apparatus 6

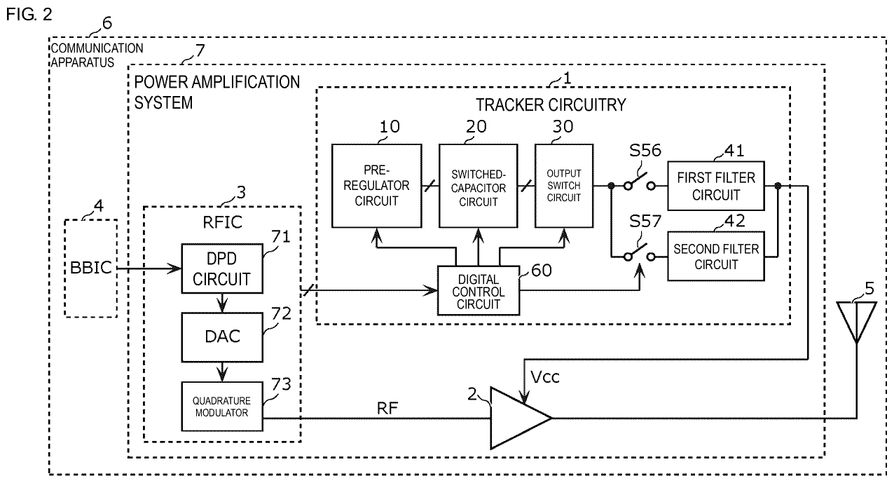

The circuit configuration of a communication apparatus 6 according to the embodiment will first be discussed below with reference to FIG. 2. FIG. 2 is a circuit diagram of the communication apparatus 6 according to the embodiment.

The circuit configuration shown in FIG. 2 is only an example. The communication apparatus 6 can be implemented by using any of a variety of circuit implementations and circuit technologies. Hence, the following explanation of the communication apparatus 6 is not to be interpreted in a limited manner.

The communication apparatus 6 in the embodiment corresponds to UE (User Equipment) in a cellular network and is typically a cellular phone, a smartphone, a tablet computer, or a wearable device, for example. The communication apparatus 6 may be an IoT (Internet of Things) sensor device, a medical/healthcare device, a vehicle, an UAV (Unmanned Aerial Vehicle) (known as a drone), or an AGV (Automated Guided Vehicle). The communication apparatus 6 may serve as a BS (Base Station) in a cellular network.

As illustrated in FIG. 2, the communication apparatus 6 includes tracker circuitry 1, a power amplifier 2, a RFIC (Radio Frequency Integrated Circuit) 3, a BBIC 4, and an antenna 5. A power amplification system 7 includes the tracker circuitry 1, the power amplifier 2, and the RFIC 3.

Based on the tracking mode, the tracker circuitry 1 is able to supply multiple discrete voltages to the power amplifier 2 as a power supply voltage Vcc. In the embodiment, as the tracking mode, a high power mode and a low power mode, which are the D-ET mode, are used. However, the tracking mode to be used is not limited to these modes.

The D-ET high power mode, which is an example of a first mode, is a voltage supply mode to be used when the output power of the power amplifier 2 is relatively high. The D-ET low power mode, which is an example of a second mode, is a voltage supply mode to be used when the output power of the power amplifier 2 is relatively low. In the high power mode, multiple discrete voltages of a first subset are used. In the low power mode, multiple discrete voltages of a second subset are used. The average voltage of the first subset is higher than that of the second subset. The average voltage of a subset refers to the average value of the discrete voltages included in the subset. The high power mode and the low power mode are not limited to the D-ET mode.

The power amplifier 2 is connected between the RFIC 3 and the antenna 5. The power amplifier 2 is also connected to the tracker circuitry 1. The power amplifier 2 is able to amplify a radio-frequency signal RF received from the RFIC 3 by using the power supply voltage Vcc supplied from the tracker circuitry 1.

The RFIC 3 is an example of a signal processing circuit that processes a radio-frequency signal. The RFIC 3 can receive a digital IQ signal from the BBIC 4 and supply the radio-frequency signal RF to the power amplifier 2. The internal configuration of the RFIC 3 will be discussed later.

The BBIC 4 is a baseband signal processing circuit that performs signal processing by using a frequency band lower than the radio-frequency signal RF. The BBIC 4 performs digital modulation on a bit sequence which represents an image signal for displaying an image and/or an audio signal for performing communication via a speaker, thereby generating a digital IQ signal. The generated IQ signal is supplied to the RFIC 3. The BBIC 4 may be omitted from the communication apparatus 6.

The antenna 5 sends the radio-frequency signal RF amplified by the power amplifier 2 to the outside of the communication apparatus 6. The antenna 5 may be omitted from the communication apparatus 6.

### 1.2 Internal Configuration of RFIC 3

The internal configuration of the RFIC 3 will be explained below with reference to FIG. 2. The RFIC 3 includes a DPD circuit 71, a DAC (Digital-to-Analog Converter) 72, and a quadrature modulator 73. The RFIC 3 may include a controller (not shown) for controlling the tracker circuitry 1. All or some of the functions of the RFIC 3 as the controller may be implemented outside the RFIC 3.

The DPD circuit 71 is able to predistort a digital IQ signal supplied from the BBIC 4 by using a mathematical-expression model for DPD. For example, the DPD circuit 71 can generate a predistorted digital IQ signal from the digital IQ signal. The predistorted digital IQ signal is supplied to the DAC 72. The DPD circuit 71 may skip DPD processing. In this case, the DPD circuit 71 can supply a digital IQ signal supplied from the BBIC 4 (that is, a digital IQ signal which is not predistorted) to the DAC 72.

The DAC 72 is able to convert the digital IQ signal supplied from the DPD circuit 71 into an analog IQ signal. The converted analog IQ signal is supplied to the quadrature modulator 73. The DAC 72 is not limited to a particular DAC, and a known DAC may be used.

The quadrature modulator 73 is able to generate a radio-frequency signal RF by performing quadrature modulation and up-conversion on the analog IQ signal supplied from the DAC 72. The generated radio-frequency signal RF is supplied to the power amplifier 2. The quadrature modulator 73 is not limited to a particular quadrature modulator, and a known quadrature modulator may be used.

The circuit configuration of the RFIC 3 is not limited to that shown in FIG. 2, which illustrates only an example of the circuit configuration of the RFIC 3. For instance, one or more or all of the DPD circuit 71, the DAC 72, and the quadrature modulator 73 may be provided outside the RFIC 3. For example, the DPD circuit 71 may be included in the BBIC 4.

A mathematical-expression model for DPD in the DPD circuit 71 will be explained below. In the embodiment, as the mathematical-expression model for DPD, a first mathematical-expression model with memory effects or a second mathematical-expression model without memory effects may be used.

The memory effects refer to a change in the distortion in a power amplifier caused by past input signals. Accordingly, concerning the first mathematical-expression model, not only a change in the distortion caused by an original (current) input signal, but also that by past input signals, are formed into a model. Compared with the second mathematical-expression model, the first mathematical-expression model can reduce the nonlinear distortion but increases a calculation load.

In the embodiment, to effectively reduce the nonlinear distortion, the first mathematical-expression model and the second mathematical-expression model are switched therebetween in accordance with whether the high power mode or the low power mode is used. For example, when the high power mode is applied to the power amplifier 2, the input signal to be supplied to the power amplifier 2 is predistorted with the first mathematical-expression model. When the low power mode is applied to the power amplifier 2, the input signal to be supplied to the power amplifier 2 is predistorted with the second mathematical-expression model.

A specific example of the second mathematical-expression model without memory effects will be explained below.

$$x [ n ] = {\sum }_{i = 0}^{N - 1} {c}_{i} r [ n ] {\vert r [ n ] \vert}^{i} \qquad ( 1 )$$

$$x [ n ] : predistored signal$$

$$r [ n ] : original input signal$$

$${c}_{i} : DPD coefficients$$

$$N : polynomial order$$

The above-described expression (1) is an example of a polynomial used in the second mathematical-expression model. The mathematical-expression model using expression (1) is called a memoryless polynomial model. In expression (1), regarding the original input signal r[n], the input signal and the exponentiated input signal are multiplied by each other. The polynomial order N and the DPD coefficient cᵢ, which are parameters of the memoryless polynomial model, can be determined empirically in advance and are prestored in a memory (not shown) included in the RFIC 3, for example.

In expression (1), it can be expected that the nonlinear distortion can be reduced if the polynomial order N is increased, but on the other hand, the calculation load may be elevated. Memory effects are not reflected in expression (1). Thus, there is a limitation on reducing the nonlinear distortion by using a memoryless polynomial model.

A specific example of the first mathematical-expression model with memory effects will now be explained below.

$$x [ n ] = {\sum }_{i = 0}^{N - 1} {\sum }_{q = 0}^{Q} {c}_{qi} r [ n - q ] {\vert r [ n - q ] \vert}^{i} \qquad ( 2 )$$

$$x [ n ] : predistored signal$$

$$r [ n ] : original input signal$$

$${c}_{qi} : DPD coefficients$$

$$Q : memory depth$$

$$N : polynomial order$$

The above-described expression (2) is an example of a polynomial used in the first mathematical-expression model. The mathematical-expression model using expression (2) is called a MPM (Memory Polynomial Model). In expression (2), regarding each of the input signals r[n−q] from the past Q to the current time 0, the input signal and the exponentiated input signal are multiplied by each other. The polynomial order N, the memory depth Q, and the DPD coefficient c_{qi}, which are parameters of the MPM, can be determined empirically in advance and are prestored in a memory (not shown) included in the RFIC 3, for example.

In expression (2), it can be expected that the nonlinear distortion can be reduced if the polynomial order N and the memory depth Q are increased, but on the other hand, the number of parameters may be increased, the calculation load may be elevated, and the convergence properties when the DPD coefficient c_{qi} is determined may be decreased.

$$x [ n ] = {\sum }_{i = 0}^{N - 1} {\sum }_{q = 0}^{Q} {c}_{qi} r [ n - q ] {\vert r ⌈ n - q ⌉ \vert}^{i} ( 3 - 1 ) \qquad ( 3 )$$

$$+ {\sum }_{i = 1}^{{N}_{d}} {\sum }_{m = 1}^{{M}_{d}} {\sum }_{q = 0}^{{Q}_{d}} {d}_{qmi} r ⌈ n - q ⌉ {\vert r ⌈ n - q - m ⌉ \vert}^{i} ( 3 - 2 )$$

$$+ {\sum }_{i = 1}^{{N}_{e}} {\sum }_{m = 1}^{{M}_{e}} {\sum }_{q = 0}^{{Q}_{e}} {e}_{qmi} r ⌈ n - q ⌉ {\vert r ⌈ n - q - m ⌉ \vert}^{i} ( 3 - 3 )$$

$$x [ n ] : predistored signal$$

$$r [ n ] : original input signal$$

$${c}_{qi} , {d}_{qmi} , {e}_{qmi} : DPD coefficients$$

$$Q : sync memory depth$$

$$N : sync order$$

$${Q}_{d} : lag memory depth$$

$${M}_{d} : maximum lag$$

$${N}_{d} : lag order$$

$${Q}_{e} : lead memory depth$$

$${M}_{e} : maximum lead$$

$${N}_{e} : lead order$$

The above-described expression (3) is an example of a polynomial used in the first mathematical-expression model. The mathematical-expression model using expression (3) is called a GMP (Generalized Memory Polynomial Model). In expression (3), a sync term (3-1) is coupled with a Lag term (3-2) and a Lead term (3-3). The sync term (3-1) is the same as the term in expression (2) for MPM. In the Lag term (3-2), the input signal and the exponentiated past input signal are multiplied by each other. In the Lead term (3-3), the input signal and the exponentiated future input signal are multiplied by each other. The polynomial orders N, N_{d}, Nₑ, the memory depths Q, and the DPD coefficients c_{qi}, d_{qmi}, e_{qmi} of the individual terms, which are parameters of the GMP, can be determined empirically in advance and are prestored in a memory (not shown) included in the RFIC 3, for example.

In expression (3), it can be expected that the nonlinear distortion can be reduced if the memory depths Q, Q_{d}, and Qₑ of the individual terms and the cross widths M_{d} and Mₑ are increased, but on the other hand, the number of parameters may be increased, the calculation load may be elevated, and the convergence properties when the DPD coefficients c_{qi}, d_{qmi}, e_{qmi} are determined may be decreased.

The effect of reducing the nonlinear distortion becomes greater in ascending order of the memoryless polynomial model, MPM, and GMP, at the same time, however, the number of parameters becomes increased and the calculation load (namely, power consumption) becomes larger in the same order. That is, the GMP can reduce the nonlinear distortion by a greater level than the MPM and the memoryless polynomial model, and the MPM can reduce the nonlinear distortion by a greater level than the memoryless polynomial model.

Conversely, the memoryless polynomial model can reduce the calculation load by a greater amount than the MPM and GMP. The MPM can reduce the calculation load by a greater amount than the GMP. Additionally, the memoryless polynomial model requires a smaller amount of memory for storing the parameters than the MPM and GMP. The MPM requires a smaller amount of memory for storing the parameters than the GMP.

The first mathematical-expression model is not restricted to MPM and GMP. That is, as the first mathematical-expression model, a mathematical expression different from the above-described expressions (2) and (3) may be used. The second mathematical-expression model is not restricted to the memoryless polynomial model. That is, as the second mathematical-expression model, a mathematical expression different from the above-described expression (1) may be used.

### 1.3 Circuit Configuration of Tracker Circuitry 1

The circuit configuration of the tracker circuitry 1 will be described below with reference to FIG. 2. The tracker circuitry 1 includes a pre-regulator circuit 10, a switched-capacitor circuit 20, an output switch circuit 30, first and second filter circuits 41 and 42, switches S56 and S57, and a digital control circuit 60.

The pre-regulator circuit 10 can convert an input voltage supplied from a DC power source (not shown) into a regulated voltage by using a power inductor. The pre-regulator circuit 10 includes a power inductor and a switch. The power inductor is an inductor used for stepping-up and/or stepping-down a DC (Direct Current) voltage. The power inductor is disposed in series with a DC path. The power inductor may be connected between the DC path and a ground (that is, the power inductor may be connected in parallel with the DC path). The pre-regulator circuit 10 configured as described above may also be called a magnetic regulator and/or a DC-to-DC converter.

The switched-capacitor circuit 20 includes plural capacitors and plural switches. The switched-capacitor circuit 20 is able to generate multiple discrete voltages having the respective discrete voltage levels from the voltage supplied from the pre-regulator circuit 10. In the embodiment, the switched-capacitor circuit 20 can generate three or more discrete voltages. The switched-capacitor circuit 20 may also be called a switched-capacitor voltage balancer.

The output switch circuit 30 can selectively output at least one of the multiple discrete voltages generated by the switched-capacitor circuit 20 to the power amplifier 2. More specifically, in the D-ET high power mode, the output switch circuit 30 is able to selectively output, among the three or more discrete voltages, at least one of discrete voltages forming a first subset to the power amplifier 2. In the D-ET low power mode, the output switch circuit 30 is able to selectively output, among the three or more discrete voltages, at least one of discrete voltages forming a second subset to the power amplifier 2.

For example, if three or more discrete voltages generated by the switched-capacitor circuit 20 are (V1, V2, V3, V4) and satisfy the relationship V1<V2<V3<V4, (V2, V3, V4) can be used as the first subset, while (V1, V2, V3) can be used as the second subset. The average voltage (V2+V3+V4)/3 of the first subset is higher than the average voltage (V1+V2+V3)/3 of the second subset. Alternatively, as the first subset, (V1, V3, V4) may be used, and, as the second subset, (V1, V2, V3) may be used. In this case, too, the average voltage (V1+V3+V4)/3 of the first subset is higher than the average voltage (V1+V2+V3)/3 of the second subset. The first subset and the second subset are not limited to the above-described examples.

The first and second filter circuits 41 and 42 can attenuate noise from multiple discrete voltages to be supplied to the power amplifier 2. The first and second filter circuits 41 and 42 may also be called a pulse shaping filter or a transition shaping filter.

The switch S56 is an ON/OFF switch for the first filter circuit 41. The switch S57 is an ON/OFF switch for the second filter circuit 42. The switch S56 is connected between the output switch circuit 30 and the first filter circuit 41. The switch S57 is connected between the output switch circuit 30 and the second filter circuit 42.

The digital control circuit 60 is able to control the pre-regulator circuit 10, switched-capacitor circuit 20, output switch circuit 30, and switches S56 and S57, based on a digital control signal from the RFIC 3.

It may be possible to omit some of the pre-regulator circuit 10, switched-capacitor circuit 20, output switch circuit 30, first and second filter circuits 41 and 42, switches S56 and S57, and digital control circuit 60 from the tracker circuitry 1. In one example, the pre-regulator circuit 10 may be omitted from the tracker circuitry 1. In another example, the first and second filter circuits 41 and 42 and the switches S56 and S57 may be omitted from the tracker circuitry 1. A desired combination of elements selected from the pre-regulator circuit 10, switched-capacitor circuit 20, output switch circuit 30, first and second filter circuits 41 and 42, and switches S56 and S57 may be integrated into a single circuit. Instead of the pre-regulator circuit 10 and the switched-capacitor circuit 20, the tracker circuitry 1 may include plural voltage supply circuits, as in U.S. Pat. No. 10,686,407. In this case, the output switch circuit 30 may be configured to select at least one of the plural voltage supply circuits.

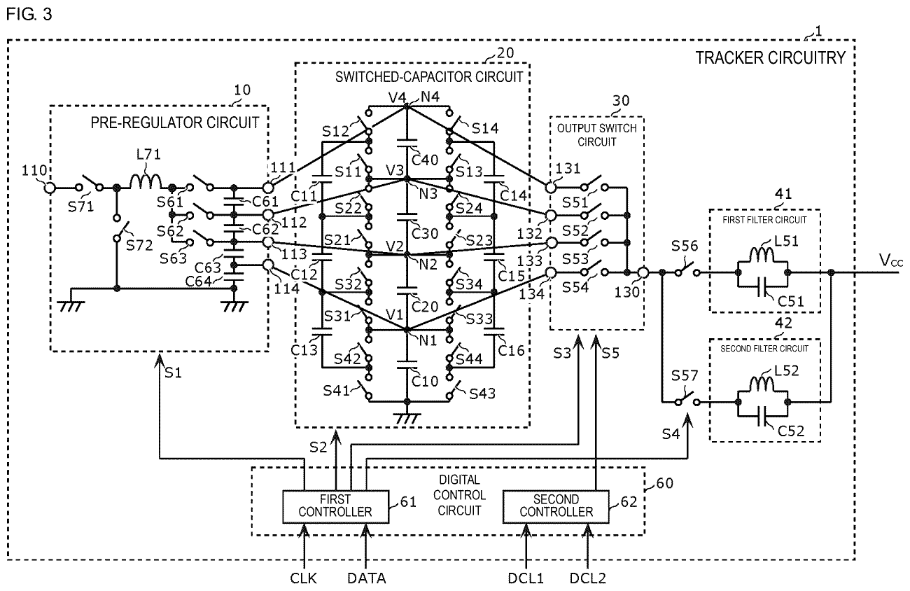

The circuit configurations of the individual circuits included in the tracker circuitry 1 will be discussed below with reference to FIG. 3. FIG. 3 is a circuit diagram of the tracker circuitry 1 according to the embodiment.

The circuit configuration shown in FIG. 3 is only an example. The tracker circuitry 1 can be implemented by using any of a variety of circuit implementations and circuit technologies. Hence, the following explanation of the tracker circuitry 1 is not to be interpreted in a limited manner.

### 1.3.1 Circuit Configuration of Switched-Capacitor Circuit 20

The circuit configuration of the switched-capacitor circuit 20 will first be discussed below with reference to FIG. 3. As illustrated in FIG. 3, the switched-capacitor circuit 20 includes capacitors C11 through C16, capacitors C10, C20, C30, and C40, and switches S11 through S14, S21 through S24, S31 through S34, and S41 through S44. Energy and electric charge are input from the pre-regulator circuit 10 into the switched-capacitor circuit 20 via nodes N1 through N4 and are output from the switched-capacitor circuit 20 to the output switch circuit 30 via the nodes N1 through N4.

The capacitors C11 through C16 each serve as a flying capacitor (may also be called a transfer capacitor). That is, each of the capacitors C11 through C16 is used for stepping up or stepping down the regulated voltage supplied from the pre-regulator circuit 10. More specifically, the capacitors C11 through C16 transfer electric charge between the capacitors C11 through C16 and the nodes N1 through N4 so that voltages V1 through V4 (voltages with respect to a ground potential) which satisfy the relationship of V1:V2:V3:V4=1:2:3:4 can be maintained at the nodes N1 through N4, respectively. The voltages V1 through V4 correspond to multiple discrete voltages having the respective discrete voltage levels.

The capacitor C11 has two electrodes. One of the two electrodes of the capacitor C11 is connected to one end of the switch S11 and to one end of the switch S12. The other one of the two electrodes of the capacitor C11 is connected to one end of the switch S21 and to one end of the switch S22.

The capacitor C12 has two electrodes. One of the two electrodes of the capacitor C12 is connected to one end of the switch S21 and to one end of the switch S22. The other one of the two electrodes of the capacitor C12 is connected to one end of the switch S31 and to one end of the switch S32.

The capacitor C13 has two electrodes. One of the two electrodes of the capacitor C13 is connected to one end of the switch S31 and to one end of the switch S32. The other one of the two electrodes of the capacitor C13 is connected to one end of the switch S41 and to one end of the switch S42.

The capacitor C14 has two electrodes. One of the two electrodes of the capacitor C14 is connected to one end of the switch S13 and to one end of the switch S14. The other one of the two electrodes of the capacitor C14 is connected to one end of the switch S23 and to one end of the switch S24.

The capacitor C15 has two electrodes. One of the two electrodes of the capacitor C15 is connected to one end of the switch S23 and to one end of the switch S24. The other one of the two electrodes of the capacitor C15 is connected to one end of the switch S33 and to one end of the switch S34.

The capacitor C16 has two electrodes. One of the two electrodes of the capacitor C16 is connected to one end of the switch S33 and to one end of the switch S34. The other one of the two electrodes of the capacitor C16 is connected to one end of the switch S43 and to one end of the switch S44.

As a result of repeating a first phase and a second phase, a set of the capacitors C11 and C14, a set of the capacitors C12 and C15, and a set of the capacitors C13 and C16 can each complementarily perform charging and discharging.

More specifically, in the first phase, the switches S12, S13, S22, S23, S32, S33, S42, and S43 are ON. As a result, for example, one of the two electrodes of the capacitor C12 is connected to the node N3, the other one of the two electrodes of the capacitor C12 and one of the two electrodes of the capacitor C15 are connected to the node N2, and the other one of the two electrodes of the capacitor C15 is connected to the node N1.

In the second phase, the switches S11, S14, S21, S24, S31, S34, S41, and S44 are ON. As a result, for example, one of the two electrodes of the capacitor C15 is connected to the node N3, the other one of the two electrodes of the capacitor C15 and one of the two electrodes of the capacitor C12 are connected to the node N2, and the other one of the two electrodes of the capacitor C12 is connected to the node N1.

As a result of repeating the first phase and the second phase, when, for example, one of the capacitors C12 and C15 is being charged from the node N2, the other one of the capacitors C12 and C15 can discharge to the capacitor C30. That is, the capacitors C12 and C15 can complementarily perform charging and discharging.

As in the set of the capacitors C12 and C15, as a result of repeating the first phase and the second phase, a set of the capacitors C11 and C14 and a set of the capacitors C13 and C16 can also each complementarily perform charging and discharging.

The capacitors C10, C20, C30, and C40 each serve as a smoothing capacitor. That is, the capacitors C10, C20, C30, and C40 are respectively used for holding and smoothing the voltages V1 through V4 at the nodes N1 through N4.

The capacitor C10 is connected between the node N1 and a ground. More specifically, one of two electrodes of the capacitor C10 is connected to the node N1, while the other one of the two electrodes of the capacitor C10 is connected to a ground.

The capacitor C20 is connected between the nodes N2 and N1. More specifically, one of two electrodes of the capacitor C20 is connected to the node N2, while the other one of the two electrodes of the capacitor C20 is connected to the node N1.

The capacitor C30 is connected between the nodes N3 and N2. More specifically, one of two electrodes of the capacitor C30 is connected to the node N3, while the other one of the two electrodes of the capacitor C30 is connected to the node N2.

The capacitor C40 is connected between the nodes N4 and N3. More specifically, one of two electrodes of the capacitor C40 is connected to the node N4, while the other one of the two electrodes of the capacitor C40 is connected to the node N3.

The switch S11 is connected between one of the two electrodes of the capacitor C11 and the node N3. More specifically, one end of the switch S11 is connected to one of the two electrodes of the capacitor C11. The other end of the switch S11 is connected to the node N3.

The switch S12 is connected between one of the two electrodes of the capacitor C11 and the node N4. More specifically, one end of the switch S12 is connected to one of the two electrodes of the capacitor C11. The other end of the switch S12 is connected to the node N4.

The switch S21 is connected between one of the two electrodes of the capacitor C12 and the node N2. More specifically, one end of the switch S21 is connected to one of the two electrodes of the capacitor C12 and to the other one of the two electrodes of the capacitor C11. The other end of the switch S21 is connected to the node N2.

The switch S22 is connected between one of the two electrodes of the capacitor C12 and the node N3. More specifically, one end of the switch S22 is connected to one of the two electrodes of the capacitor C12 and to the other one of the two electrodes of the capacitor C11. The other end of the switch S22 is connected to the node N3.

The switch S31 is connected between the other one of the two electrodes of the capacitor C12 and the node N1. More specifically, one end of the switch S31 is connected to the other one of the two electrodes of the capacitor C12 and to one of the two electrodes of the capacitor C13. The other end of the switch S31 is connected to the node N1.

The switch S32 is connected between the other one of the two electrodes of the capacitor C12 and the node N2. More specifically, one end of the switch S32 is connected to the other one of the two electrodes of the capacitor C12 and to one of the two electrodes of the capacitor C13. The other end of the switch S32 is connected to the node N2. That is, the other end of the switch S32 is connected to the other end of the switch S21.

The switch S41 is connected between the other one of the two electrodes of the capacitor C13 and a ground. More specifically, one end of the switch S41 is connected to the other one of the two electrodes of the capacitor C13. The other end of the switch S41 is connected to a ground.

The switch S42 is connected between the other one of the two electrodes of the capacitor C13 and the node N1. More specifically, one end of the switch S42 is connected to the other one of the two electrodes of the capacitor C13. The other end of the switch S42 is connected to the node N1. That is, the other end of the switch S42 is connected to the other end of the switch S31.

The switch S13 is connected between one of the two electrodes of the capacitor C14 and the node N3. More specifically, one end of the switch S13 is connected to one of the two electrodes of the capacitor C14. The other end of the switch S13 is connected to the node N3. That is, the other end of the switch S13 is connected to the other end of the switch S11 and to the other end of the switch S22.

The switch S14 is connected between one of the two electrodes of the capacitor C14 and the node N4. More specifically, one end of the switch S14 is connected to one of the two electrodes of the capacitor C14. The other end of the switch S14 is connected to the node N4. That is, the other end of the switch S14 is connected to the other end of the switch S12.

The switch S23 is connected between one of the two electrodes of the capacitor C15 and the node N2. More specifically, one end of the switch S23 is connected to one of the two electrodes of the capacitor C15 and to the other one of the two electrodes of the capacitor C14. The other end of the switch S23 is connected to the node N2. That is, the other end of the switch S23 is connected to the other end of the switch S21 and to the other end of the switch S32.

The switch S24 is connected between one of the two electrodes of the capacitor C15 and the node N3. More specifically, one end of the switch S24 is connected to one of the two electrodes of the capacitor C15 and to the other one of the two electrodes of the capacitor C14. The other end of the switch S24 is connected to the node N3. That is, the other end of the switch S24 is connected to the other end of the switch S11, to the other end of the switch S22, and to the other end of the switch S13.

The switch S33 is connected between the other one of the two electrodes of the capacitor C15 and the node N1. More specifically, one end of the switch S33 is connected to the other one of the two electrodes of the capacitor C15 and to one of the two electrodes of the capacitor C16. The other end of the switch S33 is connected to the node N1. That is, the other end of the switch S33 is connected to the other end of the switch S31 and to the other end of the switch S42.

The switch S34 is connected between the other one of the two electrodes of the capacitor C15 and the node N2. More specifically, one end of the switch S34 is connected to the other one of the two electrodes of the capacitor C15 and to one of the two electrodes of the capacitor C16. The other end of the switch S34 is connected to the node N2. That is, the other end of the switch S34 is connected to the other end of the switch S21, to the other end of the switch S32, and to the other end of the switch S23.

The switch S43 is connected between the other one of the two electrodes of the capacitor C16 and a ground. More specifically, one end of the switch S43 is connected to the other one of the two electrodes of the capacitor C16. The other end of the switch S43 is connected to a ground.

The switch S44 is connected between the other one of the two electrodes of the capacitor C16 and the node N1. More specifically, one end of the switch S44 is connected to the other one of the two electrodes of the capacitor C16. The other end of the switch S44 is connected to the node N1. That is, the other end of the switch S44 is connected to the other end of the switch S31, to the other end of the switch S42, and to the other end of the switch S33.

Based on a control signal S2, the ON/OFF state of a first set of switches including the switches S12, S13, S22, S23, S32, S33, S42, and S43 and that of a second set of switches including the switches S11, S14, S21, S24, S31, S34, S41, and S44 are switched therebetween in a complementary manner. More specifically, in the first phase, the switches included in the first set are ON, while the switches included in the second set are OFF. Conversely, in the second phase, the switches included in the first set are OFF, while the switches included in the second set are ON.

For example, in one of the first and second phases, the capacitors C11 through C13 charge the capacitors C10 through C40, and in the other one of the first and second phases, the capacitors C14 through C16 charge the capacitors C10 through C40. That is, the capacitors C10 through C40 are constantly charged from the capacitors C11 through C13 or from the capacitors C14 through C16. Hence, even if a current flows from the nodes N1 through N4 to the output switch circuit 30 at high speed, the nodes N1 through N4 are recharged quickly, thereby reducing potential variations at the nodes N1 through N4.

The switched-capacitor circuit 20 is operated in this manner so as to maintain a substantially equal voltage across each of the capacitors C10, C20, C30, and C40. More specifically, at the nodes N1 through N4 labeled with V1 through V4, respectively, the voltages V1 through V4 (voltages with respect to a ground potential) which satisfy the relationship of V1:V2:V3:V4=1:2:3:4 can be maintained. The voltage levels of the voltages V1 through V4 correspond to multiple discrete voltage levels that can be supplied to the output switch circuit 30 from the switched-capacitor circuit 20.

The voltage ratio (V1:V2:V3:V4) is not restricted to (1:2:3:4). For example, the voltage ratio (V1:V2:V3:V4) may be (1:2:4:8).

The configuration of the switched-capacitor circuit 20 is not restricted to that shown in FIG. 3, which illustrates only an example of the circuit configuration of the switched-capacitor circuit 20. Although the switched-capacitor circuit 20 shown in FIG. 3 is configured to supply four discrete voltages, the number of discrete voltages is not limited to four. The switched-capacitor circuit 20 may be configured to supply any number of multiple (two or more) discrete voltages. For example, if the switched-capacitor circuit 20 supplies two discrete voltages, it may include only at least the capacitors C12 and C15 and switches S21 through S24 and S31 through S34.

### 1.3.2 Circuit Configuration of Output Switch Circuit 30

The circuit configuration of the output switch circuit 30 will be described below with reference to FIG. 3. As illustrated in FIG. 3, the output switch circuit 30 includes input terminals 131 through 134, switches S51 through S54, and an output terminal 130.

The output terminal 130 is connected to the first and second filter circuits 41 and 42. The output terminal 130 is a terminal for supplying a power supply voltage selected from the voltages V1 through V4 to the power amplifier 2 via the first filter circuit 41 and/or the second filter circuit 42.

The input terminals 131 through 134 are connected to the nodes N4 through N1, respectively, of the switched-capacitor circuit 20. The input terminals 131 through 134 are terminals for receiving the voltages V4 through V1, respectively, from the switched-capacitor circuit 20.

The switch S51 is connected between the input terminal 131 and the output terminal 130. More specifically, the switch S51 has a terminal connected to the input terminal 131 and a terminal connected to the output terminal 130. With this connection configuration, the switch S51 is changed between ON and OFF based on a control signal S3, thereby making it possible to selectively connect the input terminal 131 to the output terminal 130 or disconnect the input terminal 131 from the output terminal 130.

The switch S52 is connected between the input terminal 132 and the output terminal 130. More specifically, the switch S52 has a terminal connected to the input terminal 132 and a terminal connected to the output terminal 130. With this connection configuration, the switch S52 is changed between ON and OFF based on the control signal S3, thereby making it possible to selectively connect the input terminal 132 to the output terminal 130 or disconnect the input terminal 132 from the output terminal 130.

The switch S53 is connected between the input terminal 133 and the output terminal 130. More specifically, the switch S53 has a terminal connected to the input terminal 133 and a terminal connected to the output terminal 130. With this connection configuration, the switch S53 is changed between ON and OFF based on the control signal S3, thereby making it possible to selectively connect the input terminal 133 to the output terminal 130 or disconnect the input terminal 133 from the output terminal 130.

The switch S54 is connected between the input terminal 134 and the output terminal 130. More specifically, the switch S54 has a terminal connected to the input terminal 134 and a terminal connected to the output terminal 130. With this connection configuration, the switch S54 is changed between ON and OFF based on the control signal S3, thereby making it possible to selectively connect the input terminal 134 to the output terminal 130 or disconnect the input terminal 134 from the output terminal 130.

The switches S51 through S54 are controlled to be ON mutually exclusively. That is, only one of the switches S51 through S54 is turned ON, while the remaining switches are turned OFF. This enables the output switch circuit 30 to output one voltage selected from the voltages V1 through V4.

The circuit configuration of the output switch circuit 30 is not limited to that shown in FIG. 3, which illustrates only an example of the circuit configuration of the output switch circuit 30. Among others, the switches S51 through S54 may be configured in any manner if they can selectively connect at least one of the four input terminals 131 through 134 to the output terminal 130. In one example, the output switch circuit 30 may include another switch between a set of the switches S51 through S53 and a set of the switch S54 and the output terminal 130. In another example, the output switch circuit 30 may include another switch between a set of the switches S51 and S52 and a set of the switches S53 and S54 and the output terminal 130.

If the switched-capacitor circuit 20 supplies two discrete voltages having the respective discrete voltage levels, the output switch circuit 30 may include only at least two of the switches S51 through S54.

### 1.3.3 Circuit Configuration of Pre-Regulator Circuit 10

The configuration of the pre-regulator circuit 10 will be discussed below with reference to FIG. 3. As illustrated in FIG. 3, the pre-regulator circuit 10 includes an input terminal 110, output terminals 111 through 114, switches S61 through S63 and S71 and S72, a power inductor L71, and capacitors C61 through C64.

The input terminal 110 is an input terminal for a DC voltage. That is, the input terminal 110 is a terminal for receiving an input voltage from a DC power source.

The output terminal 111 is an output terminal for the voltage V4. That is, the output terminal 111 is a terminal for supplying the voltage V4 to the switched-capacitor circuit 20. The output terminal 111 is connected to the node N4 of the switched-capacitor circuit 20.

The output terminal 112 is an output terminal for the voltage V3. That is, the output terminal 112 is a terminal for supplying the voltage V3 to the switched-capacitor circuit 20. The output terminal 112 is connected to the node N3 of the switched-capacitor circuit 20.

The output terminal 113 is an output terminal for the voltage V2. That is, the output terminal 113 is a terminal for supplying the voltage V2 to the switched-capacitor circuit 20. The output terminal 113 is connected to the node N2 of the switched-capacitor circuit 20.

The output terminal 114 is an output terminal for the voltage V1. That is, the output terminal 114 is a terminal for supplying the voltage V1 to the switched-capacitor circuit 20. The output terminal 114 is connected to the node N1 of the switched-capacitor circuit 20.

The switch S71 is connected between the input terminal 110 and one end of the power inductor L71. More specifically, the switch S71 has a terminal connected to the input terminal 110 and a terminal connected to one end of the power inductor L71. With this connection configuration, as a result of the switch S71 being changed between ON and OFF based on a control signal S1, the switch S71 can selectively connect the input terminal 110 to one end of the power inductor L71 or disconnect the input terminal 110 from the end of the power inductor L71.

The switch S72 is connected between one end of the power inductor L71 and a ground. More specifically, the switch S72 has a terminal connected to one end of the power inductor L71 and a terminal connected to a ground. With this connection configuration, as a result of the switch S72 being changed between ON and OFF based on the control signal S1, the switch S72 can selectively connect one end of the power inductor L71 to a ground or disconnect this end of the power inductor L71 from the ground.

The switch S61 is connected between the other end of the power inductor L71 and the output terminal 111. More specifically, the switch S61 has a terminal connected to the other end of the power inductor L71 and a terminal connected to the output terminal 111. With this connection configuration, as a result of the switch S61 being changed between ON and OFF based on the control signal S1, the switch S61 can selectively connect the other end of the power inductor L71 to the output terminal 111 or disconnect the other end of the power inductor L71 from the output terminal 111.

The switch S62 is connected between the other end of the power inductor L71 and the output terminal 112. More specifically, the switch S62 has a terminal connected to the other end of the power inductor L71 and a terminal connected to the output terminal 112. With this connection configuration, as a result of the switch S62 being changed between ON and OFF based on the control signal S1, the switch S62 can selectively connect the other end of the power inductor L71 to the output terminal 112 or disconnect the other end of the power inductor L71 from the output terminal 112.

The switch S63 is connected between the other end of the power inductor L71 and the output terminal 113. More specifically, the switch S63 has a terminal connected to the other end of the power inductor L71 and a terminal connected to the output terminal 113. With this connection configuration, as a result of the switch S63 being changed between ON and OFF based on the control signal S1, the switch S63 can selectively connect the other end of the power inductor L71 to the output terminal 113 or disconnect the other end of the power inductor L71 from the output terminal 113.

One of two electrodes of the capacitor C61 is connected to the switch S61 and to the output terminal 111. The other one of the two electrodes of the capacitor C61 is connected to the switch S62, to the output terminal 112, and to one of two electrodes of the capacitor C62.

One of the two electrodes of the capacitor C62 is connected to the switch S62, to the output terminal 112, and to the other one of the two electrodes of the capacitor C61. The other one of the two electrodes of the capacitor C62 is connected to a path connecting the switch S63, the output terminal 113, and one of two electrodes of the capacitor C63.

One of the two electrodes of the capacitor C63 is connected to the switch S63, to the output terminal 113, and to the other one of the two electrodes of the capacitor C62. The other one of the two electrodes of the capacitor C63 is connected to the output terminal 114 and to one of two electrodes of the capacitor C64.

One of the two electrodes of the capacitor C64 is connected to the output terminal 114 and to the other one of the two electrodes of the capacitor C63. The other one of the two electrodes of the capacitor C64 is connected to a ground.

The switches S61 through S63 are controlled to be ON mutually exclusively. That is, only one of the switches S61 through S63 is turned ON, while the remaining switches are turned OFF. Turning ON only one of the switches S61 through S63 enables the pre-regulator circuit 10 to vary the voltage to be supplied to the switched-capacitor circuit 20 between the voltage levels of the voltages V2 through V4.

The pre-regulator circuit 10 configured as described above is able to supply electric charge to the switched-capacitor circuit 20 via at least one of the output terminals 111 through 114.

If the input voltage is to be converted into only one regulated voltage, the pre-regulator circuit 10 may include only at least the switches S71 and S72 and the power inductor L71.

### 1.3.4 Circuit Configuration of First Filter Circuit 41 and Second Filter Circuit 42

The circuit configurations of the first and second filter circuits 41 and 42 according to the embodiment will be explained below with reference to FIG. 3.

The first filter circuit 41 includes a parallel circuit (LC parallel circuit) of an inductor L51 and a capacitor C51. One end of the parallel circuit of the inductor L51 and the capacitor C51 is connected to the switch S56. The other end of the parallel circuit of the inductor L51 and the capacitor C51 is connected to the power amplifier 2.

The second filter circuit 42 includes a parallel circuit of an inductor L52 and a capacitor C52. One end of the parallel circuit of the inductor L52 and the capacitor C52 is connected to the switch S57. The other end of the parallel circuit of the inductor L52 and the capacitor C52 is connected to the power amplifier 2.

The first filter circuit 41 connected in this manner is switched between ON and OFF by the switch S56, while the second filter circuit 42 connected in this manner is switched between ON and OFF by the switch S57. The first and second filter circuits 41 and 42 can thus switch between ON and OFF of a band elimination filter used for removing noise from multiple discrete voltages. For example, under the opening/closing control of the switches S56 and S57, three types of band elimination filters indicated by the following modes (1), (2), and (3) can be implemented.

(1) The switch S56 is closed and the switch S57 is opened, so that the first filter circuit 41 is connected between the output switch circuit 30 and the power amplifier 2 and the second filter circuit 42 is not connected therebetween. Then, the first filter circuit 41 functions as a band elimination filter, while the second filter circuit 42 does not function as a band elimination filter.

(2) The switch S56 is opened and the switch S57 is closed, so that the second filter circuit 42 is connected between the output switch circuit 30 and the power amplifier 2 and the first filter circuit 41 is not connected therebetween. Then, the second filter circuit 42 functions as a band elimination filter, while the first filter circuit 41 does not function as a band elimination filter.

(3) The switches S56 and S57 are both closed, so that the first filter circuit 41 and the second filter circuit 42 are both connected between the output switch circuit 30 and the power amplifier 2. Then, the first and second filter circuits 41 and 42 both serve as a band elimination filter.

The opening/closing of the switches S56 and S57 can be controlled based on the channel bandwidth (that is, the modulation bandwidth) of a radio-frequency signal RF, for example. If the power amplifier 2 is able to amplify sending signals of multiple frequency bands, the opening/closing of the switches S56 and S57 may be controlled based on the frequency band of a sending signal to be amplified by the power amplifier 2, for example. The opening/closing of the switches S56 and S57 may be controlled in a different manner.

The circuit configurations of the first and second filter circuits 41 and 42 are not limited to those shown in FIG. 3, which illustrates only examples of the circuit configurations of the first and second filter circuits 41 and 42. For example, the first filter circuit 41 and/or the second filter circuit 42 may be constituted by a series circuit of an inductor and a capacitor (LC series circuit). In this case, the LC series circuit may be connected between a ground and a path connecting the output switch circuit 30 and the power amplifier 2.

### 1.3.5 Circuit Configuration of Digital Control Circuit 60

The circuit configuration of the digital control circuit 60 will now be explained below. As illustrated in FIG. 3, the digital control circuit 60 includes a first controller 61 and a second controller 62.

The first controller 61 processes a serial data signal (DATA) based on a clock signal (CLK) supplied from the RFIC 3 so as to generate control signals S1 through S4. The serial data signal is a data signal transmitted bit by bit on a single signal line or circuit.

The control signal S1 is a signal for controlling the opening/closing states of the switches S61 through S63, S71, and S72 included in the pre-regulator circuit 10. The control signal S2 is a signal for controlling the opening/closing states of the switches S11 through S14, S21 through S24, S31 through S34, and S41 through S44 included in the switched-capacitor circuit 20. The control signal S3 is a signal for controlling the opening/closing states of the switches S51 through S54 included in the output switch circuit 30 when the APT mode is applied to the power amplifier 2. The control signal S4 is a signal for controlling the opening/closing state of the switch S56 for the first filter circuit 41 and that of the switch S57 for the second filter circuit 42.

For the clock signal to be used by the first controller 61 to process the serial data signal, a signal line different from that for the serial data signal is used. However, this is only an example. For instance, the clock signal may be transmitted on the same signal line for the serial data signal.

In the embodiment, the single serial data signal is used for controlling the pre-regulator circuit 10, switched-capacitor circuit 20, output switch circuit 30, and switches S56 and S57. However, plural serial data signals may be used.

The second controller 62 processes DCL (Digital Control Logic/Line) signals (DCL1, DCL2) supplied from the RFIC 3 so as to generate a control signal S5. The DCL signals are an example of parallel data signals. The parallel data signals are data signals simultaneously transmitted on plural signal lines or circuits in parallel.

The DCL signals (DCL1, DCL2) are generated by the RFIC 3 based on an envelope signal of a radio-frequency signal when the D-ET mode is applied to the power amplifier 2. Accordingly, the control signal S5 is a signal for controlling the opening/closing states of the switches S51 through S54 included in the output switch circuit 30 when the D-ET mode is applied to the power amplifier 2.

Each of the DCL signals (DCL1, DCL2) is a one-bit signal. The voltages V1 through V4 are each represented by a combination of two one-bit signals. For example, V1, V2, V3, and V4 are represented by “00”, “01”, “10”, and “11”, respectively. For the representation for the voltage level, Gray code may be used.

In the embodiment, in the D-ET mode, two DCL signals are used for controlling the output switch circuit 30. However, the number of DCL signals is not restricted to two. For example, any desired number (one or three or more) of DCL signals may be used in accordance with the number of voltage levels that the individual switches of the output switch circuit 30 can select. The digital control signal used for controlling the output switch circuit 30 is not limited to a DCL signal.

### 1.4 Power Amplification Method

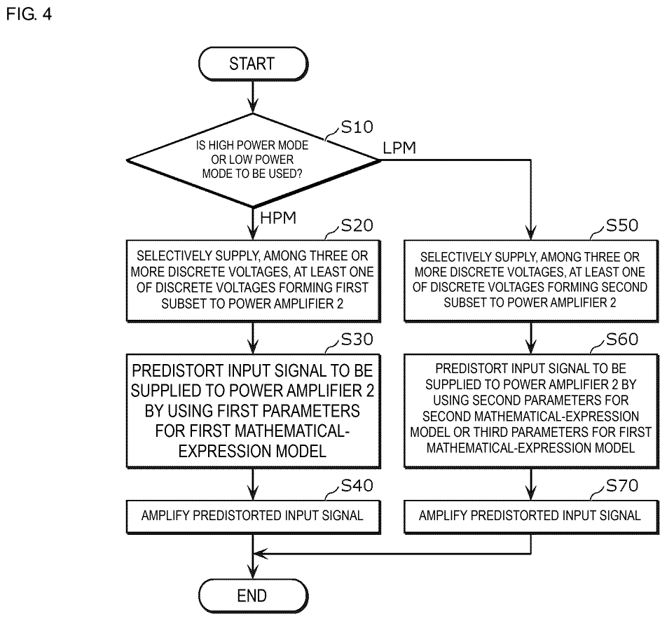

A power amplification method according to the embodiment will be described below with reference to FIG. 4. FIG. 4 is a flowchart illustrating the power amplification method according to the embodiment.

It is first determined whether the high power mode or the low power mode is to be used in the D-ET mode (S10).

If the high power mode is to be used (HPM in S10), the output switch circuit 30 selectively supplies, among three or more discrete voltages, at least one of discrete voltages forming the first subset to the power amplifier 2 (S20). Whether the high power mode is being used can be determined by measuring which of the multiple discrete voltages generated by the switched-capacitor circuit 20 is being supplied to the power amplifier 2.

Then, the RFIC 3 predistorts an input signal to be supplied to the power amplifier 2 by using first parameters (also referred to as a first parameter set) for the first mathematical-expression model with memory effects (S30). More specifically, the DPD circuit 71 calculates a predistorted digital IQ signal by using a predetermined polynomial order, memory depth, and DPD coefficient, for example, as the first parameters for expression (2) or (3), and the DAC 72 converts the calculated predistorted digital IQ signal into a predistorted analog IQ signal. Then, the quadrature modulator 73 performs quadrature modulation and up-conversion on the predistorted analog IQ signal supplied from the DAC 72, thereby generating a predistorted radio-frequency signal RF.

Then, the power amplifier 2 amplifies the predistorted input signal (radio-frequency signal RF) by using the first subset among the three or more discrete voltages (S40). With this operation, even though the influence of the memory effects is intensified due to the supplying of a relatively high power supply voltage Vcc in the high power mode, the nonlinear distortion which is varied by the memory effects can be effectively reduced.

In contrast, if the low power mode is to be used (LPM in S10), the output switch circuit 30 selectively supplies, among the three or more discrete voltages, at least one of discrete voltages forming the second subset to the power amplifier 2 (S50). Whether the low power mode is being used can be determined by measuring which of the multiple discrete voltages generated by the switched-capacitor circuit 20 is being supplied to the power amplifier 2.

Then, the RFIC 3 predistorts an input signal to be supplied to the power amplifier 2 by using second parameters (also referred to as a second parameter set) for the second mathematical-expression model without memory effects or third parameters for the first mathematical-expression model (S60). More specifically, the DPD circuit 71 calculates a predistorted digital IQ signal by using a predetermined polynomial order and DPD coefficient, for example, as the second parameters for expression (1). Alternatively, the DPD circuit 71 calculates a predistorted digital IQ signal by using a predetermined polynomial order, memory depth, and DPD coefficient, for example, as the third parameters (also referred to as a third parameter set) for expression (2) or (3). The number of third parameters is smaller than that of first parameters. To put it another way, the number of first parameters is larger than that of third parameters. The DAC 72 then converts the calculated predistorted digital IQ signal into a predistorted analog IQ signal. Then, the quadrature modulator 73 performs quadrature modulation and up-conversion on the predistorted analog IQ signal supplied from the DAC 72, thereby generating a radio-frequency signal RF.

Then, the power amplifier 2 amplifies the predistorted input signal (radio-frequency signal RF) by using the second subset among the three or more discrete voltages (S70). With this operation, when the influence of the memory effects is lessened due to the supplying of a relatively low power supply voltage Vcc in the low power mode, the calculation load required for the memory effects is reduced so that the power consumption can be lowered.

The relationships between the mode and the combination of a mathematical-expression model and parameters according to the above-described power amplification method can be summarized as in the following Table 1.

TABLE 1

| Mode | Combination 1 | Combination 2 |
|---|---|---|
| High power | First mathematical- | First mathematical- |
| mode | expression model | expression model |
| | First parameters | First parameters |
| Low power | Second mathematical- | First mathematical- |
| mode | expression model | expression model |
| | Second parameters | Third parameters |

### 1.5 Advantages and Others

As described above, the power amplification system 7 according to the embodiment includes the power amplifier 2, the output switch circuit 30, and the DPD circuit 71. The output switch circuit 30 is configured to selectively output at least one of three or more discrete voltages to the power amplifier 2. The DPD circuit 71 is configured to predistort an input signal to be supplied to the power amplifier 2. The output switch circuit 30 has a first mode and a second mode. In the first mode, among the three or more discrete voltages, at least one of discrete voltages forming a first subset is selectively output. In the second mode, among the three or more discrete voltages, at least one of discrete voltages forming a second subset is selectively output. The average voltage of the first subset is higher than that of the second subset. In the first mode, the DPD circuit 71 predistorts an input signal to be supplied to the power amplifier 2 by using a first parameter for a first mathematical-expression model for DPD. In the second mode, the DPD circuit 71 predistorts an input signal to be supplied to the power amplifier 2 by using a second parameter for a second mathematical-expression model for DPD or a third parameter for the first mathematical-expression model.

In the power amplification method according to the embodiment: among three or more discrete voltages, at least one of discrete voltages forming a first subset is selectively supplied to the power amplifier 2 (S20); a first input signal to be supplied to the power amplifier 2 is predistorted with the use of a first parameter for a first mathematical-expression model for DPD (S30); the predistorted first input signal is amplified with the use of the first subset among the three or more discrete voltages (S40); among the three or more discrete voltages, at least one of discrete voltages forming a second subset is selectively supplied to the power amplifier 2 (S50); a second input signal to be supplied to the power amplifier 2 is predistorted with the use of a second parameter for a second mathematical-expression model for DPD or a third parameter for the first mathematical-expression model (S60); and the predistorted second input signal is amplified with the use of the second subset among the three or more discrete voltages (S70).

The DPD circuit 71 according to the embodiment is configured to predistort an input signal to be supplied to the power amplifier 2. In a first mode in which, among three or more discrete voltages, at least one of discrete voltages forming a first subset is selectively output to the power amplifier 2, the DPD circuit 71 predistorts an input signal to be supplied to the power amplifier 2 by using a first parameter for a first mathematical-expression model for DPD. In a second mode in which, among the three or more discrete voltages, at least one of discrete voltages forming a second subset is selectively output to the power amplifier 2, the DPD circuit 71 predistorts an input signal to be supplied to the power amplifier 2 by using a second parameter for a second mathematical-expression model for DPD or a third parameter for the first mathematical-expression model. The average voltage of the first subset is higher than that of the second subset.

With the above-described configuration, the first mathematical-expression model and the second mathematical-expression model can be switched or the parameters to be used for the first mathematical-expression model can be switched in accordance with which subset of discrete voltages among the three or more discrete voltages is supplied to the power amplifier 2. The influence of the memory effects of the power amplifier 2 in the first mode having a higher average voltage is greater than that in the second mode having a lower average voltage. The input signal is thus predistorted with the use of the first parameter for the first mathematical-expression model, so that a higher priority is given to reducing the nonlinear distortion than to lowering the calculation load (that is, lowering the power consumption) for DPD. Conversely, in the second mode having a lower average voltage, the input signal is predistorted with the use of the second parameter for the second mathematical-expression model or the first parameter for the first mathematical-expression model, so that a higher priority is given to reducing the calculation load for DPD. This configuration makes it possible to effectively reduce the nonlinear distortion while the power consumption is being regulated.

Additionally, in one example, in the power amplification system 7, the power amplification method, or the DPD circuit 71 according to the embodiment, it is possible that memory effects of the power amplifier 2 be integrated into the first mathematical-expression model and that the memory effects of the power amplifier 2 be not integrated into the second mathematical-expression model.

With this configuration, predistorting an input signal using the first mathematical-expression model can further reduce the nonlinear distortion, while predistorting an input signal using the second mathematical-expression model can further lower the calculation load.

Additionally, in one example, in the power amplification system 7, the power amplification method, or the DPD circuit 71 according to the embodiment, the number of first parameters may be greater than that of third parameters.

With this configuration, in the first mode having a higher average voltage, increasing the number of parameters (for example, raising the number of DPD coefficients by increasing the memory depth) can provide more terms for compensating for the memory effects, thereby making it possible to further reduce the nonlinear distortion. In contrast, in the second mode having a lower average voltage, decreasing the number of parameters provides fewer terms for compensating for the memory effects, thereby making it possible to further lower the calculation load.

Additionally, in one example, in the power amplification system 7 or the DPD circuit 71 according to the embodiment, the first mode and the second mode may be the D-ET mode.

Additionally, in one example, in the power amplification method according to the embodiment, at least one of the discrete voltages forming the first subset may be selected based on an envelope signal of the first input signal, while at least one of discrete voltages forming the second subset may be selected based on an envelope signal of the second input signal.

This can change the power supply voltage Vcc based on the envelope signal, thereby making it possible to improve the power efficiency.

### Additional Exemplary Embodiments

The power amplification system and the DPD method according to an embodiment of the present disclosure have been discussed above through illustration of the embodiment and modified examples thereof. However, the power amplification system and the DPD method according to an embodiment of the disclosure are not restricted to the above-described embodiment and modified examples thereof. Other embodiments implemented by combining certain elements in the above-described embodiment and modified examples thereof and other modified examples obtained by making various modifications to the above-described embodiment and modified examples thereof by those skilled in the art without departing from the scope and spirit of the disclosure are also encompassed in the disclosure. Various types of equipment integrating the above-described power amplification system are also encompassed in the disclosure.

For example, in the circuit configurations of various circuits according to the above-described embodiment, another circuit element and another wiring may be inserted onto a path connecting circuit elements and/or a path connecting signal paths illustrated in the drawings. In one example, a filter may be inserted between the DAC 72 and the quadrature modulator 73. In another example, a filter may be inserted between the power amplifier 2 and the antenna 5.

In the above-described embodiment, multiple discrete voltages are supplied from the switched-capacitor circuit to the output switch circuit. However, this configuration is only an example. For example, multiple voltages may be supplied from the respective DC-to-DC converters. If the voltage levels of multiple discrete voltages are different by equal degrees, the use of a switched-capacitor circuit is preferable, which is effective in reducing the size of a tracker module.

In the above-described embodiment, four discrete voltages are supplied to the power amplifier. However, the number of discrete voltages is not limited to four. For example, if multiple discrete voltages include at least a voltage corresponding to the maximum output power and a voltage corresponding to the most frequently generated output power, the power-added efficiency can be improved.

The present disclosure can be widely used for communication equipment, such as a cellular phone, as a power amplification system for amplifying a radio-frequency signal.

What is claimed is:

1. A power amplification system comprising:
a power amplifier;
an output switch circuit configured to selectively output at least one of three or more discrete voltages as a power supply of the power amplifier; and
a digital predistortion circuit configured to generate distortions in an input signal of the power amplifier,
wherein the output switch circuit is configured to, in a first mode, selectively output at least one of first discrete voltages in a first subset of the three or more discrete voltages as the power supply, and in a second mode, selectively output at least one of second discrete voltages in a second subset of the three or more discrete voltages as the power supply,
wherein an average voltage of the first subset is higher than an average voltage of the second subset, and
wherein the digital predistortion circuit is configured to, in the first mode, generate the distortions in the input signal of the power amplifier by using a first mathematical-expression model for digital predistortion with a first parameter set, and in the second mode, generate the distortions in the input signal of the power amplifier by using at least a different parameter set from the first parameter set.

2. The power amplification system according to claim 1, wherein:
the digital predistortion circuit is configured to, in the second mode, generate the distortions in the input signal of the power amplifier by using a second mathematical-expression model for digital predistortion with a second parameter set.

3. The power amplification system according to claim 1, wherein:
the digital predistortion circuit is configured to, in the second mode, generate the distortions in the input signal of the power amplifier by using the first mathematical-expression model with a third parameter set.

4. The power amplification system according to claim 2, wherein:
the first mathematical-expression model is integrated with memory effects of the power amplifier; and
the second mathematical-expression model is integrated without the memory effects of the power amplifier.

5. The power amplification system according to claim 3, wherein the first parameter set includes more parameters than the third parameter set.

6. The power amplification system according to claim 1, wherein the first mode and the second mode are in a category of a digital envelope tracking (D-ET) mode.

7. The power amplification system according to claim 1, wherein:
the digital predistortion circuit is configured to generate a predistorted digital IQ signal with digital distortions, the predistorted digital IQ signal being converted to the input signal of the power amplifier with the distortions, the input signal being a radio-frequency signal.

8. A power amplification method comprising:
selectively supplying, from a first subset in three or more discrete voltages, at least one of first discrete voltages in the first subset as a first power supply to a power amplifier;
generating first distortions in a first input signal of the power amplifier by using a first mathematical-expression model for digital predistortion with a first parameter set;
amplifying the first input signal with the first distortions by using the first power supply;
selectively supplying, from a second subset in the three or more discrete voltages, at least one of second discrete voltages in the second subset as a second power supply to the power amplifier;
generating second distortions in a second input signal of the power amplifier by using at least a different parameter set from the first parameter set; and
amplifying the second input signal with the second distortions by using the second power supply.

9. The power amplification method according to claim 8, wherein the generating second distortions comprises:
generating the second distortions using a second mathematical-expression model for digital predistortion with a second parameter set.

10. The power amplification method according to claim 8, wherein the generating second distortions comprises:
generating the second distortions using the first mathematical-expression model with a third parameter set.

11. The power amplification method according to claim 9, wherein:
an average voltage of the first subset is higher than an average voltage of the second subset;
the first mathematical-expression model is integrated with memory effects of the power amplifier; and
the second mathematical-expression model is integrated without the memory effects of the power amplifier.

12. The power amplification method according to claim 10, wherein:
an average voltage of the first subset is higher than an average voltage of the second subset; and
the first parameter set includes more parameters than the third parameter set.

13. The power amplification method according to claim 8, wherein:
the at least one of the first discrete voltages in the first subset is selected based on an envelope signal of the first input signal; and
the at least one of the second discrete voltages in the second subset is selected based on an envelope signal of the second input signal.

14. A digital predistortion circuit, wherein:
in a first mode that at least one of first discrete voltages of a first subset in three or more discrete voltages is selectively output as a power supply of a power amplifier, the digital predistortion circuit is configured to generate distortions in an input signal of the power amplifier by using a first mathematical-expression model for digital predistortion with a first parameter set;
in a second mode that at least one of second discrete voltages of a second subset in the three or more discrete voltages is selectively output as the power supply of the power amplifier, the digital predistortion circuit is configured to generate the distortions in the input signal of the power amplifier by using at least a different parameter set from the first parameter set; and
an average voltage of the first subset is higher than an average voltage of the second subset.

15. The digital predistortion circuit according to claim 14, wherein:
the digital predistortion circuit is configured to, in the second mode, generate the distortions in the input signal of the power amplifier by using a second mathematical-expression model for digital predistortion with a second parameter set.

16. The digital predistortion circuit according to claim 14, wherein:
the digital predistortion circuit is configured to, in the second mode, generate the distortions in the input signal of the power amplifier by using the first mathematical-expression model with a third parameter set.

17. The digital predistortion circuit according to claim 15, wherein:
the first mathematical-expression model is integrated with memory effects of the power amplifier; and
the second mathematical-expression model is integrated without the memory effects of the power amplifier.

18. The digital predistortion circuit according to claim 16, wherein the first parameter set includes more parameters than the third parameter set.

19. The digital predistortion circuit according to claim 14, wherein the first mode and the second mode are in a category of a digital envelope tracking (D-ET) mode.

20. The digital predistortion circuit according to claim 14, wherein:
the digital predistortion circuit is configured to generate a predistorted digital IQ signal with digital distortions, the predistorted digital IQ signal being converted to the input signal of the power amplifier with the distortions, the input signal being a radio-frequency signal.
